(19) United States
(12) Patent Application Publication
(10) Pub. No.: US 2004/0183702 A1
(43) Pub. Date: Sep. 23, 2004

(54) Magnetizable thermoplastic elastomers

(76) Inventors: Daniel Nachtigal, Jamaica Plain, MA (US); Craig A. Chmielewski, Shelby Township, MI (US)

Correspondence Address: FREUDENBERG-NOK GENERAL PARTNERSHIP, INTELLECTUAL PROPERTY DEPT., 47690 EAST ANCHOR COURT, PLYMOUTH, MI, 48170-2455, US

(21) Appl. No.: 10/760,662

(22) Filed: Jan. 20, 2004

Related U.S. Application Data
(63) Continuation-in-part of application No. 10/424,642, filed on Apr. 28, 2003.
(60) Provisional application No. 60/442,572, filed on Jan. 23, 2003.
(60) Provisional application No. 60/442,572, filed on Jan. 23, 2003.

(51) Int. Cl. H03M 1/22

(52) U.S. Cl. 341/16

(57) ABSTRACT

An admixture of thermoplastic polymer (such as thermoplastic elastomer), cured elastomeric polymeric material (such as thermoset elastomer), and magnetizable (ferrite) powder provide a thermoplastic elastomer featuring a relatively high loading of a magnetizable material. The admixed magnetizable thermoplastic elastomer composition, optionally cured, provides robust material properties along with good forming properties for molding magnetic components. This material is advantageous for a magnetic target wheel in an encoder.

### CROSS-REFERENCE TO OTHER APPLICATIONS

This application is a continuation-in-part application of U.S. patent application Ser. No. 10/424,642 filed on Apr. 28, 2003 which claims benefit under 35 U.S.C. §119(e) of U.S. Provisional Patent Application 60/442,572 as filed on Jan. 23, 2003. This application also claims benefit under 35 U.S.C. § 119(e) of U.S. Provisional Patent Application 60/442,572 as filed on Jan. 23, 2003.

### INTRODUCTION

This invention relates to magnetizable thermoplastic elastomers, and to the application of such elastomers in use with magnetic speed sensor targets (encoders).

Rotational speed sensors, such as those used in automotive applications, have generally been based on principles of magnetic field sensing. Targets for speed sensors, such as magnetic encoders, generally have a magnetizable substance bonded to a structural support ring with alternating magnetic poles established around the circumference of the magnetizable substance. Thermoset elastomers have been used as carriers for ferrite poweders, to provide adequate mechanical, dynamic and thermal behavior needed in press-fit conditions common in automotive wheel-speed applications. However, thermoset elastomer-based magnetic compounds are difficult to blend in production-sized rubber compounding equipment due to their high density from the loading level of ferrite. In this regard, production batch volumes weigh two to four times more than standard rubber compound batches, and handling of the material is thereby difficult. Processing of thermoset elastomer-based magnetic compounds also requires relatively expensive equipment, substantial time, and substantial labor to manufacture a fully cured article.

Thermoplastic elastomers are a potential replacement for thermoset rubbers in magnetizable compounds for encoders, but material properties respective to durability limit their potential use. In this regard, commercially available thermoplastic elastomers, when loaded with magnetizable ferrite, show substantial loss of elongation in extreme thermal conditions; durability is therefore diminished in applications such as automotive rotational speed sensors. Thermoplastic-elastomer-based magnetic encoders having loadings of about fifty percent strontium ferrite perform acceptably under certain conditions, but such encoders are generally too brittle for broad use in this type of application, especially in comparison to thermoset based encoders with a metal particle loading. For example, an encoder employed in an automotive application may have an operating temperature range of −40° C. to 125° C. To attain highly magnetizable compounds useful for magnetic speed-sensor targets, volumetric loading of ferrite in the compound preferably exceeds twenty five percent. Attempts to employ engineered thermoplastics as carriers for the magnetic ferrite in order to produce magnetic materials at these loadings have been unsuccessful insofar as the engineered thermoplastics are very brittle and difficult to handle. Moreover, the engineered thermoplastics do not demonstrate static, dynamic, and thermal durability sufficient for magnetic encoder use. Another issue of concern in use of thermoplastic-elastomer-based magnetic compounds is that material expansion and contraction due to thermal conditions often leads to stress cracking—particularly a problem when the magnetic compound is mated to a support member with a dissimilar thermal expansion coefficient. Such mated structural materials may include, for example, stainless steel or sintered iron. Consequently, engineered thermoplastics with high ferrite powder loading have not been available which are capable of withstanding weeks-long continuous operation at the elevated temperatures and other conditions required of magnetic encoders.

Thus, it is desirable to have a magnetizable material that may be readily fabricated into a magnetic encoder while maintaining the desired properties in use of the magnetic encoder.

### SUMMARY

The invention provides a magnetizable thermoplastic elastomer composition as an admixture of thermoplastic polymer, elastomeric polymer, and magnetizable powder.

In one aspect of the invention, the thermoplastic polymer is thermoplastic elastomer and the elastomeric polymer is thermoset elastomer.

In one embodiment of the invention, the admixture has a first phase and a second phase where

(a) the first phase comprises a thermoplastic polymeric material;

(b) the second phase comprises a cured elastomeric polymeric material; and

(c) the magnetizable powder is dispersed in the first phase and in the second phase.

The invention also provides an encoder of

(a) a magnetic sensor adapted to detect changes in an adjacent magnetic field; and

(b) a target wheel having a surface adjacent to the magnetic sensor and movable relative thereto, where the target wheel is made of thermoplastic polymer (such as thermoplastic elastomer), cured elastomeric polymeric material (such as thermoset elastomer), and magnetizable powder, and where the target wheel is magnetized to provide alternating magnetic polarity along the surface and, in operation, the magnetic field changes.

In one embodiment, the invention provides a target wheel for use in an encoder comprising a generally disk shaped member which is made of an admixture of thermoplastic polymer (such as thermoplastic elastomer), cured elastomeric polymeric material (such as thermoset elastomer), and magnetizable powder.

The invention also provides a method of making an magnetizable thermoplastic elastomer composition by admixing thermoplastic polymer (such as thermoplastic elastomer), cured elastomeric polymeric material (such as thermoset elastomer), and magnetizable powder. In one embodiment, the invention comprises dynamically vulcanizing the elastomeric polymeric material in the magnetizable elastomeric material.

The magnetizable thermoplastic elastomer compositions and method of this invention afford one or more benefits over compositions and methods among those known in the art, including mechanical and durability advantages of thermoset elastomer-based magnetic compounds, under the range of conditions needed for vehicle encoder applications, with the processing and manufacturing advantages of engineered thermoplastics. Further areas of applicability will become apparent from the detailed description provided hereinafter. It should be understood that the detailed description and specific examples, while indicating embodiments of the invention, are intended for purposes of illustration only and are not intended to limit the scope of the invention.

### BRIEF DESCRIPTION OF DRAWINGS

FIG. 1 is a cross sectional view of an encoder assembly;

FIG. 2 is a plan view of another embodiment of a sensor target assembly;

FIG. 3 is a partial cross section taken along line A-A in FIG. 2;

FIG. 4 is a cross sectional view of another embodiment of a sensor target assembly; and

FIG. 5 illustrates an embodiment of a method for making the compositions of the invention.

It should be noted that the figures set forth herein are intended to exemplify the general characteristics of an apparatus, materials and methods among those of this invention, for the purpose of the description of such embodiments herein. These figures may not precisely reflect the characteristics of any given embodiment, and are not necessarily intended to define or limit specific embodiments within the scope of this invention.

### DESCRIPTION

The following definitions and non-limiting guidelines must be considered in reviewing the description of this invention set forth herein.

The headings (such as “Introduction” and “Summary”) used herein are intended only for general organization of topics within the disclosure of the invention, and are not intended to limit the disclosure of the invention or any aspect thereof. In particular, subject matter disclosed in the “Introduction” may include aspects of technology within the scope of the invention, and may not constitute a recitation of prior art. Subject matter disclosed in the “Summary” is not an exhaustive or complete disclosure of the entire scope of the invention or any embodiments thereof.

The citation of references herein does not constitute an admission that those references are prior art or have any relevance to the patentability of the invention disclosed herein. All references cited in the Description section of this specification are hereby incorporated by reference in their entirety.

The description and specific examples, while indicating embodiments of the invention, are intended for purposes of illustration only and are not intended to limit the scope of the invention. Moreover, recitation of multiple embodiments having stated features is not intended to exclude other embodiments having additional features, or other embodiments incorporating different combinations of the stated features.

As used herein, the words “preferred” and “preferably” refer to embodiments of the invention that afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the invention.

As used herein, the word “include,” and its variants, is intended to be non-limiting, such that recitation of items in a list is not to the exclusion of other like items that may also be useful in the materials, compositions, devices, and methods of this invention.

In one embodiment, a blended admixture is provided of thermoplastic elastomers (TPE), thermoset elastomers in a non-vulcanized state, and magnetizable ferrite powder. Preferably, such admixtures produce flexible and magnetizable thermoplastic elastomer compositions that are fully thermoplastic in nature. In various embodiments, by blending certain amounts of desired ingredients, these thermoplastic materials can be melt-processed in standard processing equipment, such as injection molders, plastic extruders and blow molders, and yet still maintain material properties needed for use in magnetic encoders. In one embodiment, such materials are used in magnetic encoders employed under the extreme environmental conditions experienced by automotive vehicles.

Some compositional embodiments incorporate non-cured ethylene acrylic (AEM) elastomers or rubber copolymers of an acrylate and a cross-linking monomer (ACM) at desired amounts, preferably such that, even at the ferrite powder levels needed for magnetizable encoders, the material is strong and flexible enough to produce robust parts.

An advantage of various embodiments is provided insofar as the thermoset rubber is preferably maintained in a non-cured state, which in turn provides both the thermoplastic and thermoset phases of the blended material as carriers for the magnetizable ferrite. This preferably provides for high volumetric loading of the ferrite powder even as desired material properties are essentially sustained.

Moreover, the addition of non-cured rubber at the noted amounts in the embodiments preferably does not compromise processability. In this regard, the admixtures are easily processed, for example, by continuous compounding through twin-screw extrusion, fragmentation into small pellets for ease of handling through cutting, and then fabrication into components using established thermoplastic processing equipment.

In one embodiment, a thermoplastic polyester elastomer (TPE) material is blended with a thermoset elastomer, preferably in a non-vulcanized state, and with magnetizable ferrite powder to produce a flexible and magnetizable thermoplastic elastomer compound that is preferably essentially fully thermoplastic in nature. As such, the magnetizable thermoplastic elastomer compound is then preferably processed with conventional techniques employed with TPE materials and still produce desirable material characteristics, even with the loading of magnetizable powder needed for magnetic field provision.

Thermoplastic elastomers are a class of polymers in which the end use properties of vulcanized elastomers are combined with the processing advantages of thermoplastics. They allow for conventional processing techniques, such as milling, injection molding, extrusion, blow molding, and vacuum forming—allowing the production of useful articles having true elastomeric properties without compounding or vulcanization.

An example of a TPE that can be advantageously employed in the embodiments is Hyirel™ thermoplastic polyester elastomer, sold by Dupont. Examples of thermoset elastomers useful in the embodiments include ethylene acrylic elastomers (AEM), such as Vamac™ G, sold by Dupont. The AEM elastomers can be used as “solid plasticizers” to toughen, i.e., increase elongation and decrease tensile strength of the TPE compounds, but without sacrificed of heat aging performance. In an alternative embodiment, copolymers of acrylate and cross-linking monomer (ACM) elastomers are employed instead of AEM elastomers to “plasticize” TPE based compounds; examples of ACMs include Nypol™ and Hytemp™ as sold by Zeon and Noxtite™ as sold by Unimatec.

The present compositions comprise a hard magnetic material, such as magnetizable powder, including such powders that are known in the art. The hard magnetic materials used in the embodiments are preferably those materials that are ferromagnetic but retain their crystal structure once a magnetic field is applied. They are materials used to form permanent magnets. As such, they strongly resist demagnetization once they are magnetized. In general, such materials are known, and exhibit coercivities H_{c} of from about 10 to about 100 kA/m, where A/m represents an oersted unit. It should be noted that, in some cases, the materials exhibit coercivities H_{c} of above 100 kA/m. In various embodiments, the magnetizable powder is selected from the group consisting of magnetizable ferrites (such as strontium-ferrite oxide and barium-ferrite oxide), ferrite alloys (such as those containing aluminum and nickel and cobalt), rare-earth ferrite granulates; and mixtures thereof. An example of a suitable ferrite alloy containing aluminum and nickel and cobalt is Alnico™ (available from MMC Magnetics of Hauppauge, N.Y.).

Barium-ferrite has a nominal structure of BaO.6Fe₂O₃, while strontium ferrite is given as SrO.6Fe₂O₃. Alnico™ ferrites are iron alloys containing aluminum, nickel and cobalt, as well as other optional metals. Specific examples include Alnico™ 3, Alnico 8, and Alnico 9. The listed Alnico ferrites contain from about 34 to about 50% iron, from about 24 to about 35% cobalt, about 15% nickel, and from about 7 to about 8% aluminum, the percentages being based on the total weight of the alloy. Other hard materials include iron alloys having atomic formulas Fe₆₅Cr₃₂Co₃ and Fe₆₃Cr₂₅Co₁₂. A cobalt-samarium alloy of atomic formula Co₅Sm is also available.

Elongated single domain (ESD) Fe-Co material is also available as a hard magnetic material. It is an alloy containing about 9.9% iron Fe, about 5.5% Co, about 77% Pb, and about 8.6% Sn, the percentages being based on the total weight of the alloy. Other known alloys having hard magnetic properties useful for formulating the magnetizable composition embodiments include Mn—Al—C (70 wt. % Mn, 29 wt. % Al, 0.5 wt. % Ni, 0.5 wt. % C), Co-Pt (77 wt. % Pt, 23 wt. % Co) and Fe—Nd—B (66 wt. % Fe, 33 wt. % Nd, and 1 wt. % B).

A range of loadings for the magnetizable thermoplastic elastomer compound components provides useful embodiments for encoder and similar applications. The blending of non-vulcanized (non-cured) thermoset elastomer, at a ratio of from about 25% to about 75% (by weight), to the thermoplastic elastomer carrier provides extended operating temperature durability without compromising processability and magnetic performance. The magnetizable material is then added to this blend, at a level of from about 1% to about 90%, optionally at a level of from about 70% to about 90% (by weight). For sufficient magnetic strength, depending upon the volumetric ferrite loading needed for the application of the magnetizable thermoplastic elastomer compound, the composition comprises magnetizable powder at a level of from about 25% to 70%, optionally from about 30% to about 67%, optionally from about 40% to about 60% (by volume). Preferably the level of the magnetizable powder affords good processability, material strength and durability.

In a multiphase embodiment having cured (or vulcanized) elastomeric phases blended with thermoplastic phases, magnetizable compositions contain two blended polymeric phases wherein magnetizable particles of a hard magnetic material are dispersed in both polymeric phases. A first polymeric phase is made of a thermoplastic polymeric material, and the second polymeric phase contains a cured elastomeric polymeric material. The elastomeric polymeric material may be fully cured or partially cured. While providing a heterogeneous blend in a detailed sense, the blended phases are preferably of sufficiently small individual phase domains so that an overall homogeneous blend is superficially indicated.

The multiphase embodiment compositions are relatively heavily loaded with a hard magnetic material type of magnetic powder to provide compositions that can be formed into encoders and targets for rotational sensors that operate on magnetic principles. In particular, shaped articles produced from the magnetizable composition embodiments may be magnetized according to known procedures to produce alternating opposite magnetic poles along a surface of the shaped article.

The thermoplastic material and the cured elastomeric material are present in the magnetizable composition embodiments at levels sufficient to provide the necessary material and strength and durability for the application, while retaining good processability on standard plastics equipment. If the weight level of thermoplastic material is taken as 100, the level of the cured elastomeric material can generally range from about 10 to about 300. Preferably, the elastomeric material level is at 25. In another preferred embodiment, the level of elastomeric material is at least about 50. That is, the ratio of cured elastomeric material to thermoplastic material in the composition embodiments ranges from about 1:10 to about 3:1. In a preferred embodiment, the cured elastomeric material is present relatively to the thermoplastic material at a rate ratio of about 1:1 or less. Preferably, the ratio of elastomeric material to thermoplastic material is at least about 1:4. In another preferred embodiment, the elastomeric material is present at from about 50% to about 75% that of the thermoplastic material.

In a preferred multiphase embodiment, the cured elastomeric material is present as particles dispersed in a continuous thermoplastic material phase. Thus, it is preferred to provide the elastomeric material and the thermoplastic material in such a ratio that a continuous phase of thermoplastic material is produced in the blend. No matter the structure of the elastomeric and thermoplastic phases, the hard magnetic material is preferably evenly distributed in both phases. Incorporation of the hard magnetic material into both the cured elastomeric phase and the thermoplastic phase is accomplished by mixing the thermoplastic material, the hard magnetic material, and the elastomeric material in an uncured state for a time sufficient to disperse the magnetic material in both phases prior to a subsequent curing step, discussed further below.

In a preferred embodiment, the thermoplastic polymeric material used in the embodiments may be a thermoplastic elastomer (TPE). As previously noted, thermoplastic elastomers have some physical properties of rubber, such as softness, flexibility and resilience, but may be processed like thermoplastics. A transition from a melt to a solid rubber-like composition occurs fairly rapidly upon cooling. The transition is readily reversible upon heating. This is in contrast to conventional elastomers, which harden slowly (and generally irreversibly) upon heating. Thermoplastic elastomers may be processed on conventional plastic equipment such as injection molders and extruders. Scrap may generally be readily recycled.

Thermoplastic elastomers have a multi-phase structure, wherein the phases are generally intimately mixed. In many cases, the phases are held together by graft or block copolymerization. At least one phase is made of a material that is hard at room temperature but fluid upon heating. Another phase is a softer material that is rubber like at room temperature. It is common to refer to the hard phase as “crystalline” and to the soft phase as “amorphous”.

Many thermoplastic elastomers are known. They in general adapt either the A-B-A triblock structure or the (A-B)ₙ repeating structure, where A represents hard segments and B is a soft segment. Because most polymeric materials tend to be incompatible with one another, the hard and soft segments of thermoplastic elastomers tend to associate with one another to form hard and soft phases. For example, the hard segments tend to form spherical regions or domains dispersed in a continuous elastomer phase. At room temperature, the domains are hard and act as physical crosslinks tying together elastomeric chains in a 3-D network. The domains tend to lose strength when the material is heated or dissolved in a solvent. Among the most common commercially available thermoplastic elastomers are those that contain polystyrene as the hard segment.

Non-limiting examples of A-B-A type thermoplastic elastomers include polystyrene/polysiloxane/polystyrene, polystyrene/polyethylene-co-butylene/polystyrene, polystyrene/polybutadiene polystyrene, polystyrene/polyisoprene/polystyrene, poly-α-methylstyrene/polybutadiene/poly-α-methyl styrene, poly-α-methyl styrene/polyisoprene/poly-α-methyl styrene, and polyethylene/polyethylene-co-butylene/polyethylene. Triblock elastomers are available with polystyrene as the hard segment and either polybutadiene, polyisoprene, or polyethylene-co-butylene as the soft segment.

Non-limiting examples of thermoplastic elastomers having a (A-B)ₙ repeating structure include polyamide/polyether, polysulfone/polydimethylsiloxane, polyurethane/polyester, polyurethane/poly-ether, polyester/polyether, polycarbonate/polydimethylsiloxane, and polycarbonate/polyether. Similarly, styrene butadiene repeating copolymers are commercially available, as well as polystyrene/polyisoprene repeating polymers.

In a preferred embodiment, a polyester thermoplastic elastomer is used to make the magnetizable composition embodiments. Such thermoplastic elastomers are generally (A-B)ₙ type block copolymers. In one embodiment, the hard segment is made of a polyester structure formed from diacids and low molecular weight diols such as ethylene glycol and butylene. The soft segment is made of a polyester structure based on long chain polyether glycols. Polyester TPEs (such as aforementioned Hytrel™) have some rubber like properties, but may be readily formed into parts by a variety of thermoplastic processing techniques. They exhibit good toughness, resilience, resistance to creep, impact and flex fatigue, low temperature flexibility, retention of properties at elevated temperatures, and dynamic properties.

The thermoplastic polymeric material may also be selected from among solid, generally high molecular weight, plastic materials. Preferably, the materials are crystalline or semi-crystalline polymers, and more preferably have a crystallinity of at least 25 percent as measured by differential scanning calorimetry. Polymers with a high glass transition temperature are also acceptable as the thermoplastic polymeric material. The thermoplastic also preferably has a melt temperature or glass transition temperature in the range from about 80° C. to about 350° C., but the melt temperature should preferably be lower than the decomposition temperature of the thermoplastic vulcanizate.

Non-limiting examples of thermoplastic polymers include polyolefins, polyesters, nylons, polycarbonates, styrene-acrylonitrile copolymers, polyethylene terephthalate, polybutylene terephthalate, polyamides, polystyrene, polystyrene derivatives, polyphenylene oxide, polyoxymethylene, and fluorine-containing thermoplastics. Polyolefins are formed by polymerizing α-olefins such as, but not limited to, ethylene, propylene, 1-butene, 1-hexene, 1-octene, 2-methyl-1-propene, 3-methyl-1-pentene, 4-methyl-1-pentene, 5-methyl-1-hexene, and mixtures thereof. Copolymers of ethylene and propylene or ethylene or propylene with another α-olefin such as 1-butene, 1-hexene, 1-octene, 2-methyl-1-propene, 3-methyl-1-pentene, 4-methyl-1-pentene, 5-methyl-1-hexene or mixtures thereof are also contemplated. These homopolymers and copolymers, and blends of them, may be incorporated as the thermoplastic polymeric material of the embodiments.

The cured elastomeric polymeric material of the embodiments is based on the product of vulcanization or cure of elastomeric material that is well known in the art. Upon cure, the elastomeric materials become rubber-like in physical properties. For example, rubber-like materials are characterized by high levels of resilience, softness, and compression set. Many suitable elastomeric polymeric materials are known, which can be cured or vulcanized according to known procedures, such as described in the Encyclopedia of Polymer Science and Engineering, Volume 17 in the article entitled “Vulcanization”. Preferred elastomers include those that are known to withstand high temperatures as well as provide adequate chemical resistance to fluids such as those found in automotive applications. Among preferred elastomers for use in the magnetizable composition embodiments are acrylic elastomers and ethylene acrylic elastomers.

Acrylic elastomers have the ASTM designation ACM for polymers of ethylacrylate and other acrylates, and ANM for copolymers of ethyl or other acrylates with acrylonitrile. Acrylic elastomers are prepared by polymerizing so-called backbone monomers with optionally a minor amount of cure site monomer. The backbone monomers are selected from among ethyl acrylate and other acrylic monomers. Other preferred acrylic acrylate monomers to be co-polymerized together with ethyl acrylate to make acrylic elastomers include n-butyl acrylate, 2-methoxyethyl acrylate, and 2-ethoxyethyl acrylate.

The acrylic elastomers (such as aforementioned Nypol™, Hytemp™, and Noxtite™) may contain from about 1 to about 5 mole % or weight % of cure site monomers to introduce reactive sites for subsequent crosslinking. The particular cure site monomer used in an acrylic elastomer is in general proprietary to the supplier of the elastomer. Among common cure site monomers are those that contain unsaturated carbon bonds and their side chain and those that contain a carbon-chlorine bond in the side chain.

Ethylene acrylic elastomers have the ASTM designation AEM. They are based on copolymers of ethylene and acrylate monomers, with a minor amount of cure site monomer, usually containing a carboxyl group in the side chain. Curing agents or crosslinking agents may then be used to cure or vulcanize the ethylene acrylic elastomer by reacting with the functional group in the cure site monomer. Although the precise nature of the crosslinking agent is proprietary to the supplier of the ethylene acrylic elastomers, two main classes of curing of vulcanization agents for use with such elastomers are the class of diamines and the class of peroxides. Diamines have the advantage that they cure slower but can be used at higher temperatures without scorch from too fast a cure. Mixtures of curing agents may be used, as is known to those of skill in the art, to obtain a desirable cure rate in light of the temperature conditions of the reaction. Ethylene acrylic elastomers are commercially available, including Vamac™ G (diamine cured elastomers), and Vamac™ D (peroxide cured elastomers).

To make the magnetizable composition embodiments, hard magnetic material is dispersed in a blend of an elastomeric material and a thermoplastic material prior to the onset of cure of the elastomeric material. Once the hard magnetic material is dispersed throughout both the thermoplastic phase and the uncured elastomeric phase, the elastomeric phase may be cured to provide the composition embodiments, preferably while maintaining mixing of the two phases.

Because the elastomeric material and thermoplastic material are to be melt blended, mixing necessarily occurs above the softening or melting point of the higher melting component. This higher melting component is usually the thermoplastic material. It may be that such a mixing temperature is above the temperature at which the curing agent reacts with the elastomeric material. If so, care must be taken to add the curing agent at a time after mixing such that both the magnetic material is dispersed into both the thermoplastic and elastomer phases on the one hand, and the elastomeric material is cured in the presence of the thermoplastic phase on the other hand. In this regard, it is preferred to use curing agents such as diamines that are not adversely affected by high temperatures such as would occur during the melt blending of a high melting thermoplastic material. With diamine curing agents, it is preferred to use crosslinking accelerators. Preferred accelerators include guanidine derivatives such as di-ortho-tolyl guanidine (DOTG).

In a preferred embodiment, magnetizable multiphase compositions are made by dynamically vulcanizing the elastomeric particles in the presence of the thermoplastic material, while continuing to mix or masticate the mixture. As noted above, the hard magnetic material may be added to either the thermoplastic material stream or the elastomer material stream or both.

A non-limiting example of a setpoint temperature profile 500 (as a function of elapsed time) in a synthesis that may be used to form the compositional embodiments is set forth in FIG. 5. FIG. 5 show diagramatically the temperature versus time for a thermoplastic stream I and an elastomeric stream II. During time range A, the two streams are individually melt blended at temperatures sufficient to soften the polymeric material. Hard magnetic material may be added at this time to stream I, to stream I, or to both as indicated at M. A cure package may be added to stream II, either with, during, or after addition of the magnetic material. Other conventional additives and processing aids may also be added to streams I and II. During time range B, the temperature of stream II is ramped up to a higher temperature before being combined with stream I. This is usually preferred to avoid thermal shock to stream II and its curing package. As shown, the temperature of stream II is brought up to that of stream I before the streams are combined. Alternatively, the two streams may be combined at different temperatures. A curing package may be added to stream II during time range B.

Whether added in time range A, time range, or both, the cure package is added to stream II at a time sufficient to permit cure of the elastomer in stream II to a significant degree after the streams are combined. The process in FIG. 5 is conveniently carried in a twin-screw extruder apparatus. In such an apparatus, the variable time corresponds roughly to the extruder path traveled by the streams. A continuous process may be developed by adjusting screw parameters, time, and temperature. Alternatively, the streams may be treated in separate mixers and combined at the times indicated in protocol 500 of FIG. 5. In either case, it is preferred to apply mechanical energy, such as by agitating, stirring, mixing, milling, blending, etc., the combination of uncured elastomeric polymeric material, thermoplastic polymeric material, and hard magnetic material particles during the curing stage in time range C.

In a non-limiting example, a thermoplastic material is melted and stirred together with particles of a hard magnetic material. Separately, an elastomeric material is melted and optionally hard magnetic materials are added to the melted elastomeric material. In general, the thermoplastic melt is at a higher temperature than the elastomeric melt. In one embodiment, the melted stirred thermoplastic and elastomeric streams may be combined, such as in a twin screw extruder. Upon combining the thermoplastic stream and the elastomer stream, the phases continue to be mixed while a curative package is added. Conveniently, such addition can be made through a port in the twin screw extruder apparatus. Mixing is continued with the curing package for a time sufficient to partially or fully cure the elastomeric particles. In a twin screw extruder apparatus, the mixing and cure time may be conveniently adjusted by varying the length of the extruder path. The method just described will be suitable if the cure package can withstand being added to the stirred mixture at the higher temperature of the thermoplastic melt.

In another embodiment, it may be desirable to add a curative package to the elastomer stream before combining it with the thermoplastic stream. In such a case, the temperature of the elastomer stream may be ramped up at a desired rate until the curing package and elastomer mix (alternatively also including hard magnetic material particles) may be added to the thermoplastic stream with less thermal shock to the curative package. In this embodiment, it is preferred to combine the thermoplastic stream and elastomeric stream within a time after addition of the curative package to the elastomer stream that is less than the time at which the elastomer is significantly cured. As a rule of thumb, it is desired to mix the elastomer stream and thermoplastic stream within a time after addition of the curative that is less than the Ts2 of the elastomer. Ts2 is the time required, at a given temperature, for 2% cure to be completed.

In a preferred embodiment, the magnetizable compositions are incorporated into magnetic encoders, such as those used in the automotive and other industries as targets for magnetic wheel speed sensors. Encoders may be produced by a process including overmolding a magnetizable composition embodiment onto a metal case that has been pretreated with adhesive. The overmolding process may be accomplished by compression molding but would preferably be accomplished in an injection molding process. Alternatively, the encoder may be produced from the compositions in a bi-material molding process, where a different thermoplastic would be molded as a structural substrate for the magnetizable composition embodiments.

An example of an embodiment application for which the material compositional embodiments is used is a magnetic encoder for a wheel speed measuring system. Such a wheel speed measuring system has particular application in automobiles or in other systems having a need for measuring the speeds of components. An example of such an encoder is made with a previously described admixture over-molded onto a metal case pretreated with adhesive. Another example approach for making an encoder is to mold the admixture in a bi-material molding process, where a thermoplastic is molded as the structural substrate for the magnetizable TPE substance. The overmolding process is, in one embodiment, a compression-molding process, but, in an alternative embodiment, it is an injection-molding process.

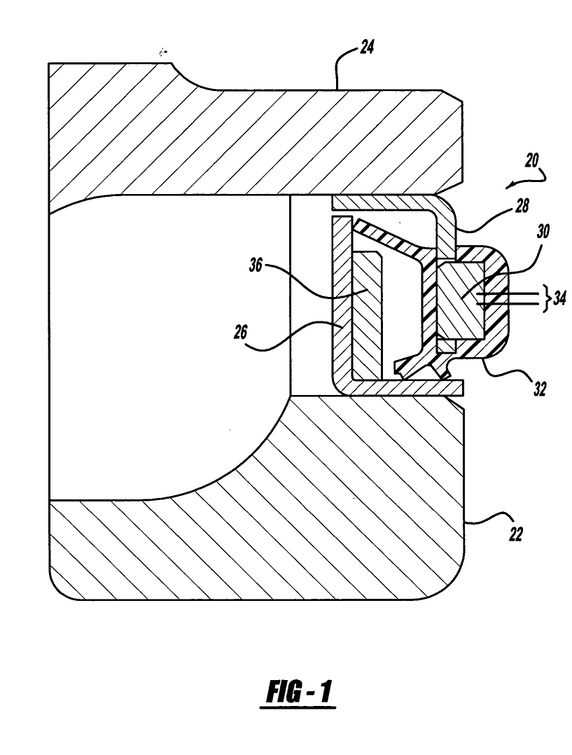

Examples of magnetic encoder assemblies and sensor target assemblies that advantageously employ the compositional embodiments are illustrated in FIGS. 1 through 4. Encoder assembly 20, for use in a rotational speed sensing device, is illustrated in FIG. 1. Encoder assembly 20 is disposed between inner race 22 and outer race 24 of a bearing assembly. The bearing assembly may be, for example, a component of a vehicle wheel bearing assembly wherein outer race 24 is attached to a vehicle frame (or other component that is rotationally fixed relative to a vehicle frame) and inner race 22 is rotationally affixed to the vehicle's wheel. As should be appreciated by those of skill, such a magnetic encoder assembly may also be employed with other types of rotary shafts in order to sense speed and/or rotational position of a shaft relative to a fixed body.

Encoder assembly 20 includes first support member 26, which is rotationally fixed to inner race 22, and second support member 28, which is rotationally fixed to outer race 24. First and second support members 26, 28 are preferably stainless steel, but alternatively are made of other suitable materials, such as thermoplastic or thermoset plastic material. Second support member 28 retains and supports rotation sensing device 30 and elastomeric seal 32 as preferably molded around sensing device 30 and sensor leads 34 protruding therefrom. Rotation sensing device 30 is, for example, a Hall-effect sensor; in an alternative embodiment, device 30 is a magneto-resistance device.

Multi-pole ring member 36 (also known as a target wheel) is mounted to first support member 26. Multi-pole ring member 36 has a surface facing rotation sensing device 30 and spaced a predetermined distance therefrom. Multi-pole ring member 36 is made of magnetizable thermoplastic elastomer admixture as described above. Multi-pole ring member 36 is preferably formed employing the previously discussed techniques associated with processing TPE materials, such as, for example, a continuous compounding via twin screw extrusion, cutting of the extrudate into small pellets, and fabrication with standard thermoplastic processing equipment. Ring member 36 then is magnetized so that magnetizable material is provided in alternating north and south poles in the circumferential direction of ring member 36. In operation, as inner race 22 rotates relative to outer race 24, these poles move alternately past rotation sensing device 30 and create a changing magnetic field for sensing by device 30.

FIGS. 2 and 3 show a sensor target assembly 200 (FIG. 3 providing assembly view 300 into cross section A-A of FIG. 2) with encoder 136 mounted to support 126. Encoder 136 is preferably formed of a magnetizable thermoplastic elastomer admixture embodiment as described above.

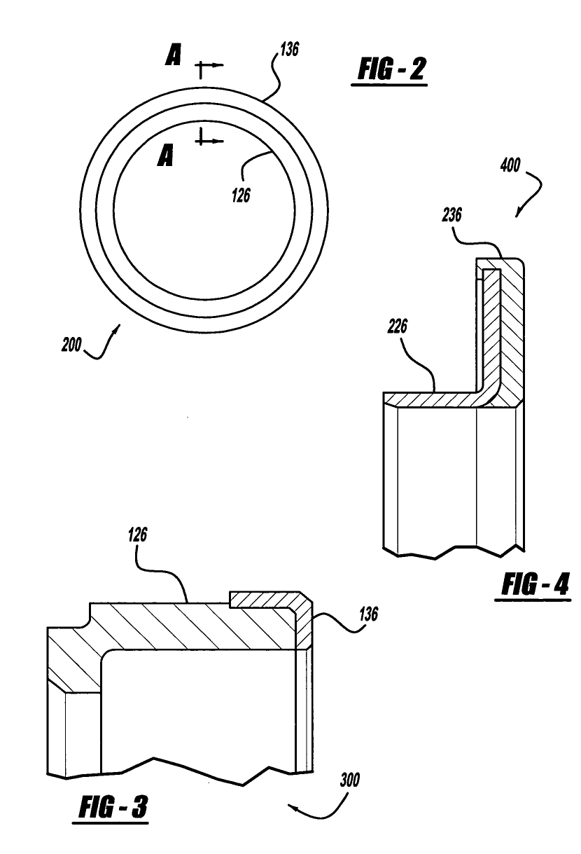

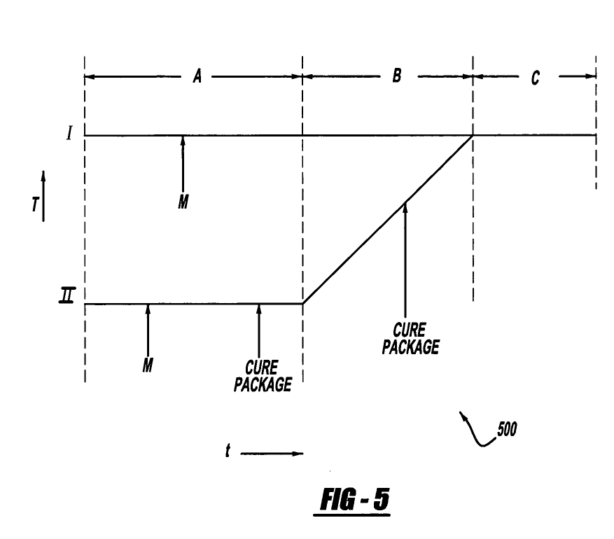

FIG. 4 shows a sensor target assembly 400 of encoder 236 secured to support 226. Again, encoder 236 is preferably formed of magnetizable thermoplastic elastomer admixture as described above.

### EXAMPLES

Examples 1 and 2: Examples of two compositions of ethylene acrylic elastomers thermoset elastomer (Vamac™) and ferrite powder in Hytrel™ thermoplastic polyester elastomer (Examples 1 as Admixture A and Example 2 as Admixture B) are presented in Table 1 and heat aging properties of these two compositions are further shown in Tables 2 and 3 to further illustrate specific embodiments.

TABLE 1
Composition of Two Magnetizable Thermoplastic
Elastomer Admixtures

| | Density | Admixture A | | Admixture B | |
|---|---|---|---|---|---|
| Component | g/cc | wt % | vol % | wt % | vol % |
| Hytrel ™ HTR 8139BK | 1.15 | 14.3 | 37.4 | 13.5 | 32.1 |
| Ferrite HM 1701 | 5.07 | 80.8 | 48.0 | 76.5 | 41.3 |
| Vamac ™ G | 1.03 | 05.0 | 14.6 | 10.0 | 26.6 |

TABLE 2
Heat Aging Properties of Magnetizable Thermoplastic Elastomer
Admixtures at 125 Degrees C in Air

| AGE TIME/Property | Admixture A | Admixture B |
|---|---|---|
| ORIGINAL PROPERTIES | | |
| Tensile Strength MPa | 12.4 | 8.2 |
| 50% Modulus Mpa | — | 7.7 |
| Elongation % | 27 | 69 |
| Hardness, Shore A, pts | 92 | 89 |
| Hardness, Shore D, pts | 59 | 46 |
| Specific Gravity | 2.99 | 2.77 |
| 70 HOURS | | |
| Tensile Strength MPa | 13.5 | 9.5 |
| 50% Modulus MPa | — | 9.1 |
| Elongation % | 46 | 116 |
| Hardness, Shore A, pts | 99 | 97 |
| Hardness, Shore D, pts | 60 | 50 |
| Surface Appearance | Good | Good |
| 168 HOURS | | |
| Tensile Strength MPa | 12.9 | 10.1 |
| 50% Modulus MPa | — | 9.5 |
| Elongation % | 25 | 94 |
| Hardness, Shore A, pts | 101 | 96 |
| Hardness, Shore D, pts | 62 | 50 |
| Surface Appearance | Poor | Good |
| 336 HOURS | | |
| Tensile Strength MPa | 14.2 | 10.3 |
| 50% Modulus MPa | — | 9.7 |
| Elongation % | 43 | 86 |
| Hardness, Shore A, pts | 100 | 95 |
| Hardness, Shore D, pts | 64 | 51 |
| Surface Appearance | Poor | Good |
| 504 HOURS | | |
| Tensile Strength MPa | 13.8 | 10.5 |
| 50% Modulus MPa | — | 9.5 |
| Elongation % | 33 | 109 |
| Hardness, Shore A, pts | 101 | 96 |
| Hardness, Shore D, pts | 61 | 50 |
| Surface Appearance | Good | Good |

Note that the elongation increases and the hardness decreases as with the level of Vamac™ ethylene acrylic elastomer (AEM) in the admixture. Table 3 shows the percentage change in the heat aging properties of Table 2 (the percentage change is always with respect to the original property value before heat aging commenced). As shown in both tables 2 and 3, heat aging generally positively enhances admixture properties.

TABLE 3
Percentage Change In Heat Aging Properties
of Magnetizable Thermoplastic Elastomer
Admixtures at 125 Degrees C. in Air

| AGE TIME/Property | Admixture A | Admixture B |
|---|---|---|
| 70 HOURS | | |
| Percentage Change in Tensile Strength | 9 | 16 |
| Percentage Change in 50% Modulus | — | 18 |
| Percentage Change in Elongation | 70 | 68 |
| Percentage Change in Hardness, Shore A | 7 | 8 |
| Percentage Change in Hardness, Shore D | 1 | 4 |
| 168 HOURS | | |
| Percentage Change in Tensile Strength | 4 | 23 |
| Percentage Change in 50% Modulus | — | 24 |
| Percentage Change in Elongation | −7 | 37 |
| Percentage Change in Hardness, Shore A | 9 | 7 |
| Percentage Change in Hardness, Shore D | 3 | 4 |
| 336 HOURS | | |
| Percentage Change in Tensile Strength | 15 | 26 |
| Percentage Change in 50% Modulus | — | 26 |
| Percentage Change in Elongation | 59 | 25 |
| Percentage Change in Hardness, Shore A | 8 | 6 |
| Percentage Change in Hardness, Shore D | 5 | 5 |
| 504 HOURS | | |
| Percentage Change in Tensile Strength | 11 | 28 |
| Percentage Change in 50% Modulus | — | 24 |
| Percentage Change in Elongation | 22 | 58 |
| Percentage Change in Hardness, Shore A | 9 | 7 |
| Percentage Change in Hardness, Shore D | 2 | 4 |

Examples 3 and 4: Magnetizable composition example embodiments are prepared according to the recipes given in Example 3 and Example 4. The weight percents and volume percents given in Examples 3 and 4 are the percentages in the final magnetizable composition. In Examples 3 and 4, half of the ferrite material is combined with the polyester elastomer and half is combined with the ethylene acrylic elastomer in separate streams. The streams are melted and stirred together with the ferrite material. The mixing streams are combined in a twin screw extruder, followed by addition of a diamine curative package for the ethylene acrylic elastomer. After further mixing for a time sufficient to cure the Vamac™ G material, the magnetizable composition is removed from the twin screw extruder. The material from the extruder is combined with carbon black and optional other processing aids and molded into a disc shaped or annulus shaped ring. The disc or annulus is magnetized according to known procedures to produce an encoder elastomer for use in the embodiments.

| | Density | Example 3 | | Example 4 | |
|---|---|---|---|---|---|
| | g/cc | wt % | vol % | wt % | vol % |
| Polyester Elastomer | 1.115 | 14.3 | 37.4 | 13.5 | 32.1 |
| Sr-Ba Ferrite | 5.07 | 80.8 | 48.0 | 76.5 | 41.3 |
| Acrylic Elastomer | 1.03 | 5.0 | 14.6 | 10.0 | 26.6 |
| Total | | 100.0 | 100.0 | 100.0 | 100.0 |

Examples 5 and 6: Examples 5 and 6 give the recipes for forming magnetizable composition example embodiments using diamine curing agents and accelerators. The mixing of separate streams, heating, temperature ramping, combining, and mixing can be readily accomplished using a twin screw extruder apparatus. The ferrite and polyester elastomer are combined in a first thermoplastic stream and melt blended. In a separate stream, the acrylic elastomer, curing accelerator, and diamine curing agent are melt blended at a temperature of about 100° C. or lower. This temperature is lower than the activation temperature of the crosslinking so that no significant crosslinking occurs in the elastomeric stream. The thermoplastic stream is stirred at a temperature of about 200° C., which is sufficient to soften or melt the polyester elastomer. To avoid thermal shock to the curing agent and accelerator, the elastomer stream is ramped up in temperature prior to being combined with the thermoplastic stream at 200° C. The ramp-up speed of the temperature of the elastomeric stream is chosen such that by the time the temperature reaches 200° C. and the elastomeric stream is combined with the thermoplastic stream, the acrylic elastomer is not significantly cured or vulcanized. Once the thermoplastic stream and elastomeric stream are combined, the streams are mixed for a further period sufficient to partially or completely cure or vulcanize the acrylic elastomer. The composition is then removed, where it can be further processed on standard thermoplastic processing equipment.

| | | Example 5 | | | | Example 6 | | | |
|---|---|---|---|---|---|---|---|---|---|
| | Density | | Charge | | | | Charge | | |
| | G/cc | Charge g | cc | Wt. % | Vol. % | Charge G | Cc | Wt. % | Vol. % |
| Polyester | 1.15 | 10.7 | 8.76 | 10.1 | 27.2 | 7.94 | 6.91 | 7.9 | 23.4 |
| Elastomer | | | | | | | | | |
| Sr-Ba | 5.11 | 82.35 | 16.12 | 82.3 | 50.0 | 86.08 | 16.85 | 86.1 | 57.0 |
| Ferrite | | | | | | | | | |
| Acrylic | 1.03 | 7.55 | 7.33 | 7.55 | 22.74 | 5.96 | 5.78 | 6.0 | 19.6 |
| Elastomer | | | | | | | | | |
| Curing | 1.10 | 0.023 | 0.021 | 0.023 | .064 | 0.018 | 0.016 | .018 | .055 |
| Accelerator | | | | | | | | | |
| Diamine | 1.28 | 0.008 | 0.006 | .008 | .018 | 0.006 | 0.005 | .006 | .016 |
| Curing | | | | | | | | | |
| Agent | | | | | | | | | |
| Total | | 100.00 | 32.23 | 100.0% | 100.0% | 100.00 | 29.55 | 100.00 | 29.55 |

In an alternative process, the strontium barium ferrite may be divided among the thermoplastic stream and elastomer stream prior to mixing the streams. Although the ferrite may be distributed between the two streams in any fashion, it is preferred that both streams contain an equal weight percent or volume percent of the ferrite. In general, it is believed that such will further enable an even distribution of ferrite particles in the thermoplastic phase and in the elastomeric phase of the magnetizable composition formed in the twin screw process.

The process of making the compositional embodiments, in which magnetic material is incorporated into a blend of thermoplastic material and elastomeric material prior to curing the elastomer, provides both thermoplastic and thermoset phases of the blended material as carriers for the magnetic materials. This allows for high volume matrix loadings of magnetic material even as desired material properties are achieved. In this regard, an advantage of the embodiments is that a material is provided which combines (a) mechanical and environmental durability advantages of thermoset-elastomer-based magnetic compounds under the range of environmental conditions needed for vehicle encoder applications with (b) ease of processing and manufacturing offered by engineered thermoplastics.

The examples and other embodiments described herein are exemplary and not intended to be limiting in describing the full scope of compositions and methods of this invention. Equivalent changes, modifications and variations of specific embodiments, materials, compositions and methods may be made within the scope of the present invention, with substantially similar results.

What is claimed is:

1. A magnetizable composition comprising an admixture of thermoplastic polymer, elastomeric polymer, and magnetizable powder.

2. A magnetizable composition according to claim 1 wherein said thermoplastic polymer provides a first phase in said composition, said elastomeric polymer provides a second phase in said composition, and said magnetizable powder is dispersed in said first phase and in said second phase.

3. A composition according to claim 1, wherein said elastomeric polymer is fully cured.

4. A composition according to claim 1, wherein said elastomeric polymer is partially cured.

5. A magnetizable thermoplastic elastomer composition according to claim 1 wherein said thermoplastic polymer is thermoplastic elastomer and said elastomeric polymer is thermoset elastomer.

6. A magnetizable thermoplastic elastomer composition according to claim 5 wherein the thermoset elastomer is an elastomer that has not been subjected to vulcanization.

7. A magnetizable thermoplastic elastomer composition according to claim 5 wherein the thermoset elastomer is selected from the group consisting of ethylene acrylic elastomers, acrylate elastomers, cross-linking monomer elastomers, and mixtures thereof.

8. A magnetizable thermoplastic elastomer composition according to claim 5 wherein the thermoplastic elastomer is from about 5% to about 50% (by weight) of the composition.

9. A magnetizable thermoplastic elastomer composition according to claim 5 wherein the thermoset elastomer is from about 3% to about 40% (by weight) of the composition.

10. A magnetizable thermoplastic elastomer composition according to claim 5 wherein the magnetizable powder is from about 1% to about 90% (by weight) of the composition.

11. A magnetizable thermoplastic elastomer composition according to claim 5 wherein the magnetizable powder is selected from the group consisting of strontium ferrite oxide, barium ferrite oxide, ferrite alloys containing aluminum and nickel and cobalt, rare-earth ferrites, and mixtures thereof.

12. A magnetizable thermoplastic elastomer composition according to claim 5 wherein the thermoplastic elastomer is thermoplastic polyester elastomer.

13. A magnetizable thermoplastic elastomer composition according to claim 5 wherein said thermoplastic elastomer provides a first phase in said composition, said thermoset elastomer provides a second phase in said composition, and said magnetizable powder is dispersed in said first phase and in said second phase.

14. A magnetizable thermoplastic elastomer composition according to claim 9, wherein said thermoset elastomer is fully cured.

15. A magnetizable thermoplastic elastomer composition according to claim 9, wherein the said thermoset elastomer is partially cured.

16. A target wheel for use in an encoder comprising a generally disk shaped member made of a thermoplastic elastomer admixture of thermoplastic elastomer, thermoset elastomer, and magnetizable powder.

17. The target wheel according to claim 16 wherein the thermoplastic elastomer is thermoplastic polyester elastomer.

18. The target wheel according to claim 16 wherein the thermoset elastomer is selected from the group consisting of ethylene acrylic elastomers, acrylate elastomers, cross-linking monomer elastomers, and mixtures thereof.

19. The target wheel according to claim 16 wherein the magnetizable powder is selected from the group consisting of strontium ferrite oxide, barium ferrite oxide, ferrite alloys containing aluminum and nickel and cobalt, rare-earth ferrites, and mixtures thereof.

20. The target wheel according to claim 16 wherein said thermoplastic elastomer provides a first phase in said target wheel, said thermoset elastomer provides a second phase in said target wheel, and said magnetizable powder is dispersed in said first phase and in said second phase.

21. The target wheel according to claim 16, wherein said thermoset elastomer is fully cured.

22. The target wheel according to claim 16, wherein the said thermoset elastomer is partially cured.

23. An encoder comprising:
(a) a magnetic sensor adapted to detect changes in an adjacent magnetic field; and
(b) a target wheel, according to claim 16, having a surface adjacent the magnetic sensor and movable relative thereto, said target wheel made of a thermoplastic elastomer admixture of thermoplastic elastomer, thermoset elastomer, and magnetizable powder, said target wheel magnetized to provide alternating magnetic polarity along said surface and, in operation, said magnetic field changes thereby.

24. The encoder according to claim 23 wherein the magnetic sensor is adapted for attachment to one of a wheel and a vehicle body in a vehicle, and the target wheel is adapted for attachment to the other of the wheel and the vehicle body.

25. The encoder according to claim 23 wherein said thermoplastic elastomer provides a first phase in said target wheel, said thermoset elastomer provides a second phase in said target wheel, and said magnetizable powder is dispersed in said first phase and in said second phase.

26. A method of making a target wheel for a rotational encoder, comprising:
(a) admixing thermoplastic elastomer, thermoset elastomer, and magnetizable powder to form a thermoplastic elastomer admixture;
(b) molding said admixture into a target wheel; and
(c) magnetizing said target wheel to provide alternating magnetic polarity along a surface of said target wheel which in rotational operation will provide a changing magnetic field for sensing by a sensor.

27. The method according to claim 26 further comprising (d) heat-aging said target wheel.

28. The method according to claim 26 wherein said molding step is achieved with a compression-molding process.

29. The method according to claim 26 wherein said molding step is achieved with an injection molding process.

30. The method according to claim 26 wherein the thermoset elastomer is an elastomer that has not been subjected to vulcanization.

31. The method according to claim 26 wherein the thermoset elastomer is selected from the group consisting of ethylene acrylic elastomers, acrylate elastomers, and cross-linking monomer elastomers.

32. The method according to claim 26 wherein the thermoplastic elastomer is thermoplastic polyester elastomer.

33. The method according to claim 32 wherein the thermoset elastomer is selected from the group consisting of ethylene acrylic elastomers, acrylate elastomers, and cross-linking monomer elastomers.

34. A method according to claim 26, wherein said molding of said admixture comprises:
(i) molding a thermoplastic as a structural substrate for said target wheel; and
(ii) over-molding said admixture onto said structural substrate.

35. A magnetizable composition comprising:
(a) a first phase conveying a thermoplastic polymeric material;
(b) a second phase comprising cured elastomeric polymeric material; and
(c) magnetizable powder dispersed in said first phase and in said second phase.

36. A composition according to claim 35, wherein said elastomeric polymeric material is fully cured.

37. A composition according to claim 35, wherein said elastomeric polymeric material is partially cured.

38. A composition according to claim 35, wherein said thermoplastic polymeric material comprises polyester thermoplastic elastomer.

39. A composition according to claim 35, wherein said elastomeric polymeric material is selected from the group consisting of acrylic elastomers, ethylene acrylic elastomers, and mixtures thereof.

40. A composition according to claim 35, wherein said thermoplastic polymeric material comprises polyester thermoplastic elastomer; said elastomeric polymeric material comprises a material selected from the group consisting of acrylic elastomers, ethylene acrylic elastomers, and mixtures thereof; and said hard magnetic material comprises from about 10% to about 90% (by volume) of said composition.

41. A composition according to claim 40, wherein said hard magnetic material comprises from about 25% to about 70% (by volume) of said composition.

42. A composition according to claim 40, wherein said elastomeric polymeric material is present at a level of from about 10% to about 300% (by weight) of said thermoplastic material.

43. A composition according to claim 40, wherein said elastomeric polymeric material is present at a level of from about 10% to about 100% (by weight) of said thermoplastic material.

44. A composition according to claim 40, wherein said elastomeric polymeric material is present at a level of from about 10% to about 100% (by weight) of said thermoplastic material.

45. A shaped article covering a magnetable composition according to claim 35.

46. An encoder comprising:
(a) an encoder case; and
(b) a shaped article comprising an encoder elastomer adhered to said case;
wherein said encoder elastomer comprises a thermoplastic polymeric material first phase and a cured elastomeric polymeric material second phase, and magnetizable particles of hard magnetic material are dispersed in said first phase and in said second phase, and wherein said encoder elastomer comprises alternating opposite magnetic poles along a surface of said article.

47. A radial encoder according to claim 46.

48. An axial encoder according to claim 46.

49. An encoder according to claim 46, wherein said elastomeric polymeric material is fully cured.

50. An encoder according to claim 46, wherein said elastomeric polymeric material is partially cured.

51. An encoder according to claim 46, wherein said thermoplastic polymeric material comprises polyester elastomer.

52. An encoder according to claim 46, wherein said elastomeric polymeric material is selected from the group consisting of acrylic elastomers, ethylene acrylic elastomers, and mixtures thereof.

53. An encoder according to claim 46, wherein said thermoplastic polymeric material comprises polyester elastomer; said elastomeric polymeric material comprises a material selected from the group consisting of acrylic elastomers, ethylene acrylic elastomers, and mixtures thereof; and said hard magnetic material comprises from about 10 percent to about 90 percent by volume of said encoder.

54. An encoder according to claim 53 wherein said hard magnetic material comprises from about 25% to about 70% (by volume) of said encoder elastomer.

55. An encoder according to claim 53, wherein said elastomeric polymeric material is present at a level of from about 10 percent to about 300 percent by weight of said thermoplastic material.

56. An encoder according to claim 53, wherein said elastomeric polymeric material is present at a level of from about 10 percent to about 100 percent by weight of said thermoplastic material.

57. An encoder according to claim 53, wherein said elastomeric polymeric material is present at a level of from about 10 percent to about 100 percent by weight of said thermoplastic material.

58. A seal assembly for a bearing comprising:
(a) an encoder adapted to be affixed to a rotating member and comprising an encoder case and an encoder elastomer adhered to said case; and
(b) a seal disposed in sealing contact with said encoder and adapted to be affixed to a stationary member;
wherein said encoder elastomer comprises:
(1) a first phase comprising a thermoplastic polymeric material, and
(2) a second phase comprising a cured elastomeric polymeric material,
wherein magnetizable particles of hard magnetic material are dispersed in said first phase and in said second phase.

59. A seal assembly according to claim 58, wherein said elastomeric polymeric material is selected from the group consisting of acrylic elastomers, ethylene acrylic elastomers, and mixtures thereof.

60. A seal assembly according to claim 58, wherein said thermoplastic polymeric material comprises polyester thermoplastic elastomer; said elastomeric polymeric material comprises a material selected from the group consisting of acrylic elastomers, ethylene acrylic elastomers, and mixtures thereof; and said hard magnetic material comprises from about 10 percent to about 90 percent by volume of said encoder elastomer.

61. A seal assembly according to claim 59 wherein said hard magnetic material comprises from about 25% to about 70% (by volume) of said encoder elastomer.

62. A seal assembly according to claim 59, wherein said elastomeric polymeric material is present at a level of from about 10 percent to about 300 percent by weight of said thermoplastic material.

63. A seal assembly according to claim 58, wherein said encoder is a radial encoder.

64. A seal assembly according to claim 58, wherein said encoder is an axial encoder.

65. A process for making a magnetizable polymer composition comprising:
(a) dispersing hard magnetic material in a blend of a thermoplastic material and elastomeric material, wherein said elastomeric material is in an uncured state or a partially cured state; and
(b) curing said elastomeric material in the presence of said thermoplastic material and said hard magnetic material.

66. A process according to claim 65, wherein said dispersing further comprises:
(1) combining thermoplastic polymeric material, uncured elastomeric polymeric material, and particles of hard magnetic material to form a combination, wherein said hard magnetic material comprises from about 10 percent to about 90 percent by volume of said combination; and
(2) applying mechanical energy to said combination to form said blend; and wherein said curing further comprises continuing to apply mechanical energy during said curing.

67. A process according to claim 65, further comprising dynamically vulcanizing said elastomeric material during said dispersing of said thermoplastic material and said hard magnetic material.

68. A process according to claim 65, carried out in a twin-screw extrusion apparatus.

69. A process according to claim 66, wherein said composition comprises from about 10 to about 300 parts of said elastomeric material per 100 parts of thermoplastic material.

70. A process according to claim 69, wherein said thermoplastic material comprises thermoplastic elastomer.

71. A process according to claim 69, wherein said elastomeric material is selected from the group consisting of acrylic elastomers, ethylene acrylic elastomers, and mixtures thereof.

72. A process according to claim 70, wherein said composition comprises from about 10 to about 100 parts of said elastomeric material per 100 parts of thermoplastic material.

73. A process according to claim 71, wherein said composition comprises from about 25 to about 100 parts of said elastomeric material per 100 parts of thermoplastic material.
